(19) United States
(12) Patent Application Publication
(10) Pub. No.: US 2005/0083713 A1
(43) Pub. Date: Apr. 21, 2005

(54) Programmable light source for edge-lit displays

(76) Inventor: Herbert Jan Karl Boks, Ann Arbor, MI (US)

Correspondence Address: Christopher W. Quinn, Esq.;Quinn Law Group, PLLC, 39555 Orchard Hill Place, Suite 245, Novi, MI, 48375, US

(21) Appl. No.: 10/965,571

(22) Filed: Oct. 14, 2004

Related U.S. Application Data
(60) Provisional application No. 60/511,900, filed on Oct. 16, 2003.

(51) Int. Cl. A47F 3/00; F21V 7/04; H03H 9/00

(52) U.S. Cl. 362/561

(57) ABSTRACT

A light source comprised of a transparent body and a printed circuit board is mounted to a transparent display panel. The transparent body is comprised of a series of light-collimating lenses. The printed circuit board comprises a series of LEDs which are arranged such that the emitted light enters the collimating lenses and then enters the transparent display panel. The substantially collimated light reflects within the display panel until it contacts a diffuse surface portion, causing the light to exit the display panel. The on/off state and intensity of the LEDs are controlled by a programmable device. The transparent body and transparent display panel are sufficiently flat to facilitate a layered arrangement of assemblies.

### CROSS-REFERENCE TO RELATED APPLICATION

This application claims the benefit of U.S. Provisional Application 60/511,900, filed Oct. 16, 2003, which is hereby incorporated by reference in its entirety.

### TECHNICAL FIELD

This invention relates to an illumination device for edge-illumination of a transparent display panel.

### BACKGROUND OF THE INVENTION

An illumination device for edge-illumination of a transparent display panel typically includes a light source in the form of a fluorescent tube mounted in the vicinity of the edge of a transparent display panel. The light emitted from the light source is directed into the transparent display panel and reflects between the inner surfaces of the transparent display panel until the light strikes a diffuse region, which causes the light to scatter and exit the transparent display panel. This principle is employed primarily in backlights of LCD displays, in lighted poster signs, in lighted name plates, in lighted EXIT signs, and in lighted message boards.

The prior art includes a series of inventions that have incorporated a generally parallel vertical arrangement of transparent display panels to create dynamic effects, such as motion simulation and variable message display. Furthermore, the prior art includes a series of inventions focused on improving the efficiency of the light source by incorporating reflectors and optics to efficiently direct the light emitted from the light source into the transparent display panels.

The technological advancements made through the prior art notwithstanding, problems exist with current products. First, achieving a directed, uniform light distribution is a challenging task. Controlling the brightness and uniformity requires appropriate selection and positioning of light sources, as well as sufficient means to direct the emitted light. These characteristics are important, especially for illumination of large display panels. Second, maintaining a light, compact structure requires an efficient arrangement of light sources and related componentry. Third, manufacturing an energy-efficient, long-lasting, safe, and reliable product has been shown to be a nontrivial task.

### SUMMARY OF THE INVENTION

The basic function of an edge-illumination device is to efficiently transmit light into an edge of a transparent display panel. Ideally, the light is evenly distributed over the edge of the transparent display panel and transmitted in a direction nearly parallel to the display surface of the display panel.

An illumination device for edge-illumination of a transparent display panel is provided. The apparatus includes a plurality of light sources, mounted to a printed circuit board, and a transparent body, positioned with respect to the plurality of light sources, such that the light emitted from the light sources is directed into the transparent body. The transparent body consists of a plurality of collimating lenses, each characterized by one external surface that is positioned adjacent one of the plurality of light sources, thus providing a surface for light to enter each of the plurality of collimating lenses. The transparent body is also characterized by a plurality of mounting brackets, which provide a means to rigidly connect the transparent body to the printed circuit board, thereby maintaining a sufficiently small air gap between the plurality of light sources and the adjacent plurality of collimating lenses. Each of the plurality of collimating lenses are also characterized by reflective internal surfaces, shaped specifically to collimate and direct the light through each lens in a near parallel manner, normal to the entry surface of each lens. The transparent body is also characterized by an external surface, positioned opposing the surfaces adjacent to the plurality of light sources, which provides a surface for the collimated light to exit the transparent body. In a preferred embodiment, a transparent display panel is positioned such that an edge of the transparent display panel is positioned in contact with the sufficiently flat exit surface of the transparent body to provide an edge through which the collimated light is able to enter the transparent display panel. The light permeates the transparent display panel by reflecting off of the internal surfaces of the transparent display panel. This internal reflection is possible only if the light has been collimated to such a degree that the light strikes the internal surfaces of the transparent display panel at a sufficiently shallow angle. The light is intended to reflect back and forth between the internal surfaces of the transparent display panel until it strikes a diffuse surface, and will upon contact be redirected to an angle steep enough with respect to the internal surface of the transparent display panel to cause the light to exit the transparent display panel.

In a preferred embodiment, the light sources are comprised of a row of low profile, surface mounted light emitting diodes, mounted to the printed circuit board. The printed circuit board comprises a connector at each end of the printed circuit board to allow connection of multiple modules into a variable length light source and for connection to a controller and power supply. A controller capable of individually altering the on/off state and the illumination intensity of the light emitting diodes is connected to the printed circuit board.

In a preferred embodiment, the controller consists of a module which connects to a personal computer via USB input. The personal computer includes software that allows the user to vary the light color and illumination timing via EEPROM/Flash software. This type of controller enables the user to make sophisticated designs without significant investment, and facilitates the mass production of a customizable module with minimal investment.

In a preferred embodiment, the thickness of the row of light emitting diodes and the transparent body is less than or equal to the thickness of the transparent display panel, which allows for a generally parallel vertical arrangement of multiple apparatuses. This generally parallel vertical arrangement of multiple apparatuses will henceforth be described as “layered” apparatuses.

The above features and advantages, and other features and advantages, of the present invention are readily apparent from the following detailed description of the best modes for carrying out the invention when taken in connection with the accompanying drawings.

### BRIEF DESCRIPTION OF THE DRAWINGS

FIG. 1 is a front view of the assembly comprising the transparent body and the printed circuit board;

FIG. 2 is a plan view of FIG. 1;

FIG. 3 is a cross sectional end view of the assembly in FIG. 2, taken at line 3-3;

FIG. 4 is an enlarged fragmented longitudinal front view of a collimating lens;

FIG. 5 is an enlarged fragmented end view of one collimating lens, depicting the means by which light is collimated by each lens;

FIG. 6 is an enlarged fragmented view of the assembly depicted in FIG. 1, positioned adjacent a transparent display panel;

FIG. 7 is a perspective view of a preferred embodiment of the apparatus, illustrating an assembly comprising a series of layered transparent display panels joined to a series of edge-lighting assemblies, and which is connected to a programmable control device.

### DESCRIPTION OF THE PREFERRED EMBODIMENT

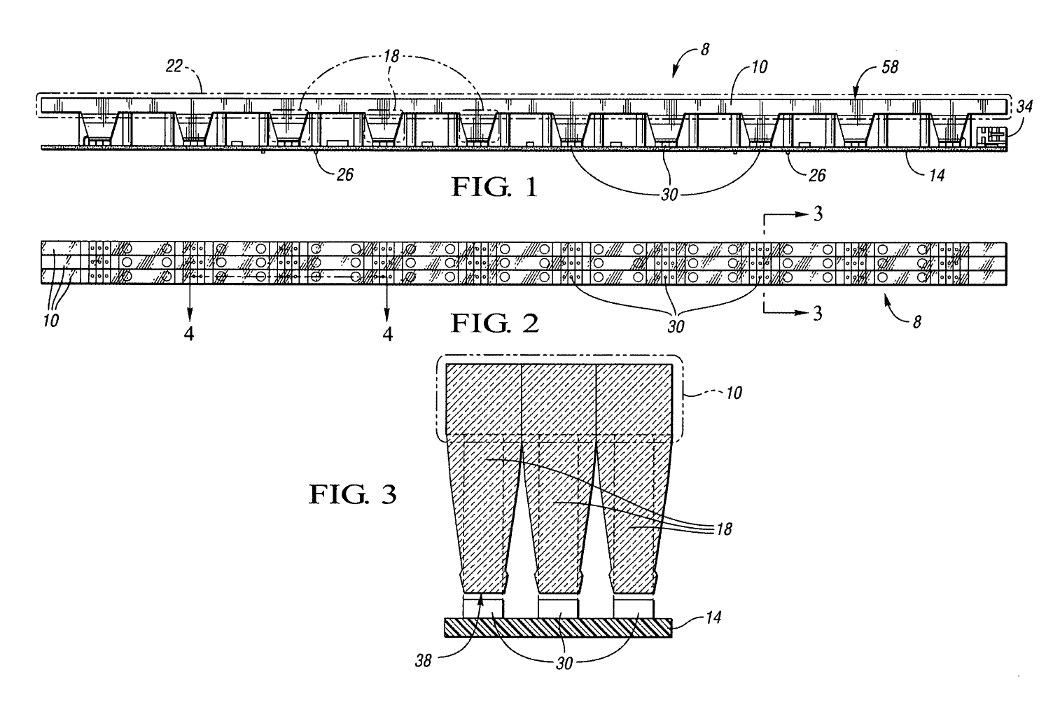

Referring to FIGS. 1 and 2, an illumination device 8, which includes a transparent body 10 and printed circuit board 14, is schematically depicted. The transparent body 10 includes a plurality of collimating lenses 18, a connecting portion 22 which connects the lenses 18 in a serial arrangement, and a plurality of hook-shaped mounting brackets 26 which provide a rigid connection of the transparent body 10 to the printed circuit board 14. The printed circuit board 14 includes a plurality of light emitting diodes (LEDs) 30 which, once the transparent body 10 and printed circuit board 14 are rigidly attached, are each positioned adjacent a corresponding one of the plurality of collimating lenses 18. The printed circuit board 14 also includes an electronic connector 34, located near one of the longitudinal ends of the printed circuit board 14.

Referring to FIG. 3, wherein like reference numbers refer to like components from FIGS. 1 and 2, each of the plurality of collimating lenses 18 is characterized by an edge 38 positioned adjacent a respective one of the LEDs 30, which allows the light emitted by each LED 30 to enter each respective lens. In a preferred embodiment, a substantially small clearance is maintained between each of the LEDs 30 and this edge 38 of each corresponding lens 18.

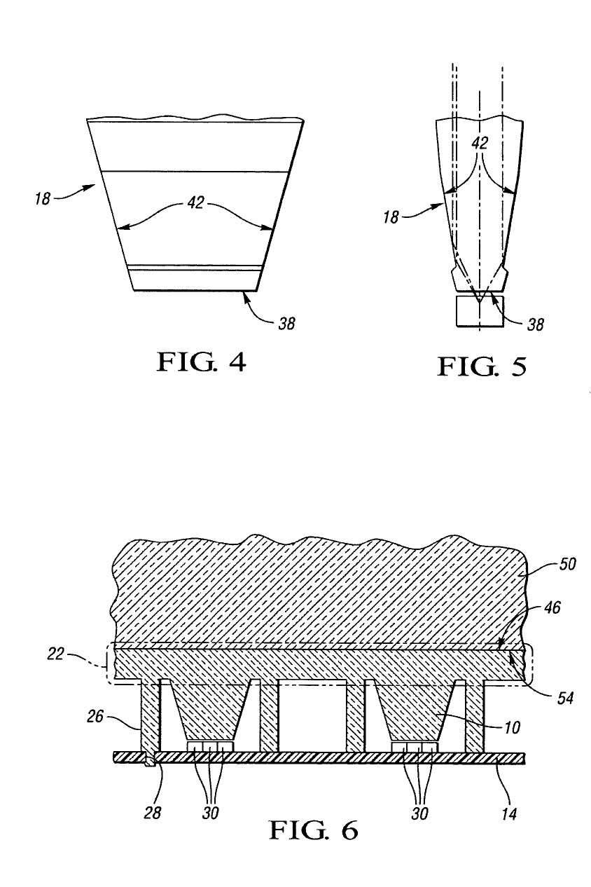

Referring to FIGS. 4 and 5, wherein like reference numbers refer to like components from FIGS. 1-3, light (represented by phantom lines) that enters each collimating lens 18 reflects off of the reflective internal side surfaces 42 of the lens. The reflective side surfaces are preferably formed by vacuum deposition of an aluminum coating.

Referring to FIG. 6, wherein like reference numbers refer to like components from FIGS. 1-5, the mounting brackets 26 are received by apertures 28 in the printed circuit board 14. The connecting portion 22 is characterized by a substantially flat surface 46 opposite the edges 38 adjacent the LEDs. A transparent display panel assembly 50 (50A, 50B and 50C) is positioned such that one edge 54 of the display panel assembly 50 is in flush contact with the substantially flat surface 46 of the connecting portion 22 of the transparent body 10. This flush contact allows the collimated light to efficiently exit the transparent body 10 and enter the transparent display panel assembly 50.

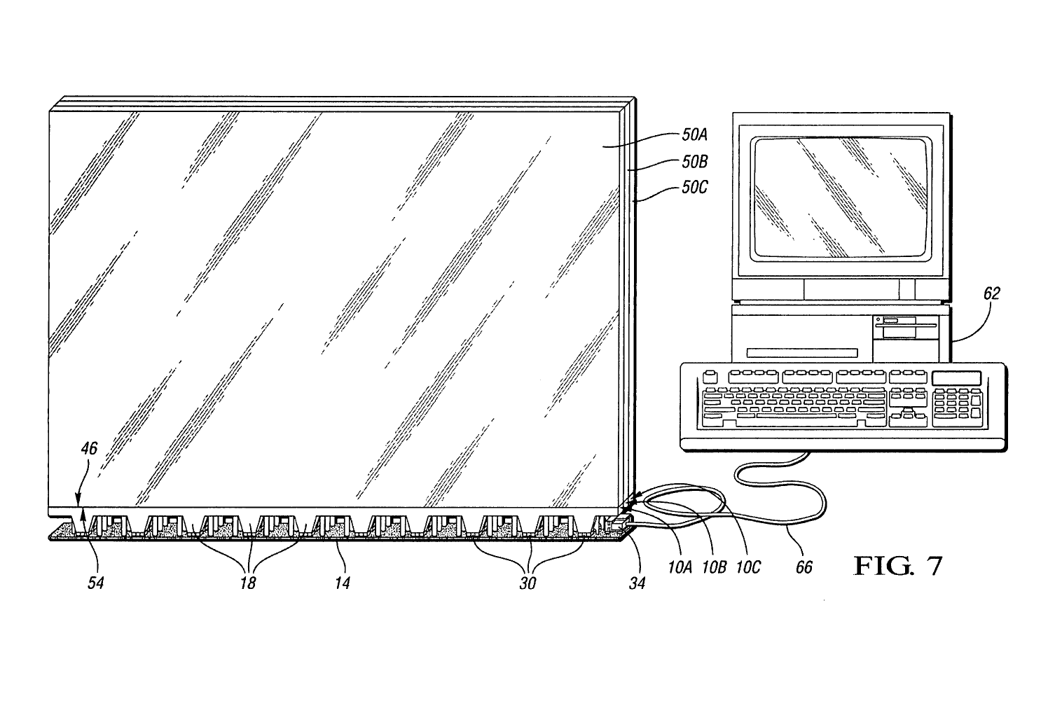

Referring to FIG. 7, wherein like reference numbers refer to like components from FIGS. 1-6, a programmable control device 62 is depicted, which is connected via wire 66 or similar means to the electronic connector 34 of a printed circuit board 14. In a preferred embodiment, there exists a plurality of layered assemblies, a first assembly including a transparent body 10A and transparent display panel 50A, a second assembly including a transparent body 10B and transparent display panel 50B, a third assembly including a transparent body 10C and transparent display panel 50C, and so on, each of these having the respective characteristics and subcomponents described previously. In a preferred embodiment, the thickness of each transparent body 10 is less than or equal to the thickness of each transparent display panel, which facilitates effective layering of assemblies. The transparent body may be an acrylic, polycarbonate or glass sheet which is cast, extruded or injection molded, for example.

In a preferred embodiment, the dimensions of each transparent display panel is 0.22″ to 0.25″ thick, 24″ (single strip) to 48″ (dual strip) wide, and 14″ to 18″ long. The preferred number of collimating lenses 18 per transparent body 10 is eight to ten, with two to three transparent bodies 10 per illumination device 8.

In a preferred manufacturing process, each transparent display panel is cut from an acrylic sheet and is then silk-screened. The transparent display panel assembly 50 is then glued to the transparent body 10 with a fast curing cement. The exposed edges of the transparent display panel assembly 50 are then covered with reflective tape. The illumination device 8 is mounted in a frame or other housing, depending on the specific application. Finally, the illumination device 8 is connected to a standard class II, 6V power supply.

In a preferred embodiment, the LEDs 30 are rated to 6V DC, 1.0A to 1.8A input voltage, maximum 330 to 560 lumen luminous output, and 4 W to 8 W average power consumption. The preferred storage capacity of the programmable control device 62 is 8 kb, with a preferred refresh rate of 80 fps.

Various features shown and described in accordance with the different embodiments of the invention illustrated may be combined.

While the best modes for carrying out the invention have been described in detail, those familiar with the art to which this invention relates will recognize various alternative designs and embodiments for practicing the invention within the scope of the appended claims.

1. An illumination device for edge-illumination of a transparent display panel, comprising:
a plurality of light sources, and
a transparent body, characterized by reflective internal side surfaces, and positioned with respect to the plurality of light sources, such that the light emitted from said light sources is directed into said transparent body.

2. The apparatus of claim 1, wherein the transparent body is characterized by a plurality of collimating lenses, each having an edge positioned adjacent a respective one of the plurality of light sources.

3. The apparatus of claim 2, wherein the plurality of collimating lenses are interconnected by a connecting portion, said connecting portion characterized by a substantially flat surface opposed from the edges adjacent to the plurality of light sources.

4. The apparatus of claim 3, wherein the light sources consist of low profile, surface mounted light emitting diodes (LEDs).

5. The apparatus of claim 4, wherein the light sources are characterized by a variable on/off state and variable illumination intensity.

6. The apparatus of claim 5, further comprising a programmable device capable of controlling the on/off state and illumination intensity of each of the plurality of light sources.

7. The apparatus of claim 6, further comprising a transparent display panel having one edge connected to said substantially flat surface.

8. The apparatus of claim 7, wherein the maximum thickness of the plurality of light sources and transparent body is less than or equal that of the thickness of the transparent display panel.

9. An illumination device for edge-illumination of a transparent display panel, comprising:
a series of interconnected collimating lenses formed in a transparent body and having reflective internal side surfaces, said transparent body being mounted to a printed circuit board, and
a corresponding series of light emitting diodes (LEDs) connected to said printed circuit board and arranged such that light emitted from each LED is received by a respective one of said series of collimating lenses.

10. An illumination device for edge-illumination of a series of transparent display panels, comprising:
a printed circuit board, comprising an electronic connector, and a plurality of light emitting diodes (LEDs), rigidly attached to a plurality of layered assemblies each including:
a plurality of interconnected collimating lenses formed in a transparent body, said transparent body being mounted to said printed circuit board and having an edge that is substantially flat, each of said plurality of collimating lenses having reflective internal side surfaces and arranged such that light emitted from each LED is received by a respective one of said plurality of collimating lenses, and
a transparent display panel, characterized by a substantially flat edge positioned adjacent the substantially flat edge of said transparent body.

11. The apparatus of claim 10, wherein the light sources are characterized by a variable on/off state and variable illumination intensity.

12. The apparatus of claim 11, wherein one of the printed circuit boards is electronically connected to a programmable device, said programmable device capable of controlling the on/off state and illumination intensity of each of the plurality of light sources.
